(19) United States
(12) Patent Application Publication
(10) Pub. No.: US 2015/0211112 A1
(43) Pub. Date: Jul. 30, 2015

(54) Method of forming by ALD a thin film of formula MYx

(71) Applicants: Commissariat A L'Energie Atomique Et Aux Energies Alternatives, Paris (FR); Centre National De La Recherche Scientifique, Paris (FR); Universite Claude Bernard Lyon 1, Villeurbanne (FR); CPE Lyon Formation Continue et Recherche, Villeurbanne (FR)

(72) Inventors: Stéphane CADOT, Genay (FR); Francois MARTIN, Grenoble (FR); Elsje QUADRELLI, Lyon (FR); Chloé THIEULEUX, Villeurbanne (FR)

(21) Appl. No.: 14/603,829

(22) Filed: Jan. 23, 2015

(30) Foreign Application Priority Data
Jan. 24, 2014 (FR) 14.50598

(51) Int. Cl. C23C 16/30; C23C 16/44; C23C 16/56; C23C 16/455; C23C 16/46

(52) U.S. Cl. CPC C23C 16/305; C23C 16/45553; C23C 16/46; C23C 16/56; C23C 16/4402; C23C 16/4408; C23C 16/45536

(57) ABSTRACT

This method relates to the preparation by ALD of a thin film of formula MYₓ, x being in the range from 1.5 to 3.1.

According to this method, MYₓ is deposited by ALD on a substrate, from at least one precursor of metal M, and at least one precursor of element Y;
M being tungsten and/or molybdenum;
the degree of oxidation of metal M in the precursor of metal M being in the range from 3 to 6;
the metal of the precursor of metal M only including simple or multiple bonds M-Z and/or M-M with Z=C, N, H, and any combination of these atoms;
Y being sulfur and/or selenium;
the substrate temperature being lower than or equal to 350° C.

### FIELD OF THE INVENTION

The invention relates to a method of forming a thin-film material of MYₓ type, M being tungsten and/or molybdenum, and Y being sulfur and/or selenium.

The present invention can particularly be used in electronics.

### BACKGROUND

The use of materials of MYₓ type (M=Mo, W; Y=S, Se) in catalysis or in the field of lubricant coatings has caused the development of various manufacturing techniques, and more specifically:
the sulphiding of metal oxides MoO₃ and WO₃ with H₂S or with a H₂/H₂S mixture;
the thermal decomposition of thiomolybdates or of thiotungstates;
reactive cathode sputtering;
the decomposition (thermal and/or tribological) of molybdenum or tungsten dithiocarbamates, thiophosphates, or thioxanthates;
the chemical vapor deposition (CVD) by reaction between a precursor of the metal such as MoF₆, MoCl₅, or Mo(CO)₆, and a sulphur precursor such as sulphur hydrogen or elemental sulphur;
single precursor chemical vapor deposition (CVD) by thermal decomposition of molybdenum dithiocarbamates or tetrathiolate (IV);
the deposition of a material of MY₂ type (WS₂) by atomic layer deposition (ALD) from volatile halogenated precursors of the metal (WF₆).

However, such methods generally result in:
porous deposits; or
deposits systematically containing impurities, particularly O, C, Cl, and F, given that the only examples of direct ALD of MoS₂ or WS₂ described to date use Mo and W chlorides or fluorides; or
the forming of corrosive by-products such as HF and HCl capable of deteriorating the substrate.

Further, they do not enable to accurately control the thickness and the homogeneity of the deposit forming the thin film.

On the other hand, the thin film obtained according to such methods has crystal planes which do not all have the same direction relative to the substrate having the deposition performed thereon. In other words, such methods generally do not enable to control the orientation of the crystal planes in the deposited film. Although, for example, this feature is not a disadvantage in catalysis, it may be a problem, particularly for a use in electronics.

Other examples of prior art methods enabling to form MoS₂-type thin film comprise:
sulphiding a preformed deposit of MoO₂ with elemental sulphur at 1,000° C.;
depositing by CVD oxide MoO₃ and elemental sulphur at 650° C.;
the physical transport of MoS₂ in vapor phase at 900° C.;
depositing by CVD MoCl₅+H₂S at 600° C. This method enables to form an oriented film of 50 nanometers of MoS₂. However, it does not enable to optimally cover the substrate as soon as the first nanometers have been deposited;
performing a cathode sputtering, which may also enable to form an oriented deposit. However, this method does not enable to very accurately control the thickness, particularly due to the lack of homogeneity of the deposit. Indeed, such a technique enables to control the thickness of the deposit to within a few tens of nanometers.

However, such techniques have the disadvantage of generally requiring very high temperatures, often higher than 650° C., which are incompatible with integrated circuit manufacturing methods. Further, they generally do not allow a controlled forming of hybrid films, that is, a film containing a mixture of different elements M and/or of different elements Y which have been successively deposited.

An option is to exfoliate MY₂ films by means of an adhesive. However, such a technique is limited in terms of reproducibility and of applicability at a large scale. Further, it does not enable to form hybrid thin films at an industrial scale. It generally requires a very pure and very crystalline material.

To overcome these problems, the Applicant has developed a method enabling to prepare, in mild conditions (deposition temperature lower than 350° C., no halogenated impurities), an MYₓ-type thin film by successive self-limited depositions of a precursor containing M and of another precursor containing Y. Thus, this method enables not only to control the thickness of the thin film more accurately than prior art methods, but also to form hybrid films.

### DISCUSSION OF THE INVENTION

The present invention relates to a method of preparing a MYₓ material appearing in the form of a thin film which may be amorphous, partially crystalline, or fully crystalline.

“Thin film” means a layer of material having its thickness advantageously in the range from 0.5 to 100 nanometers, more advantageously smaller than 10 nanometers, and more advantageously still smaller than 5 nanometers.

In relatively mild conditions in terms of implementation temperature, the method forming the object of the invention enables to control the thickness and the stoichiometry of the MYₓ thin film.

Further, the method according to the present invention also enables to form a hybrid MYₓ thin film where M is molybdenum and/or or tungsten and Y is sulfur and/or selenium.

More specifically, the object of the present invention relates to a method of preparing by ALD a thin film of formula MYₓ, x being in the range from 1.5 to 3.1. This method comprises the step of depositing by ALD (“Atomic Layer Deposition”) MYₓ on a substrate from at least one precursor of metal M, and at least one precursor of element Y;
M being tungsten and/or molybdenum (in other words, M is selected from the group formed of tungsten, molybdenum, and or the tungsten/molybdenum mixture);
the degree of oxidation of metal M in the precursor of metal M being in the range from 3 to 6, preferably equal to 3, 4, or 6, and more advantageously still equal to 4 or 6;
the metal of the precursor of metal M only comprising M-Z and/or M-M bonds with Z=C, N, II, and any combination of these atoms;
Y being sulphur and/or selenium (in other words, Y is selected from the group formed of sulphur, selenium, and or the sulphur/selenium mixture);
the substrate temperature being lower than or equal to 350° C.

The above-mentioned M-Z and M-M bonds are bonds which may be simple or multiple.

Advantageously in formula MYₓ, x is in the range from 1.8 to 3.1, more advantageously from 1.9 to 3, and more advantageously still from 2 to 3. According to a particularly advantageous embodiment, x=2.

Typically, techniques used to analyze the composition of the thin film of formula MYₓ include the following techniques:
X-ray photoelectron spectrometry: XPS;
Raman spectrometry;
X-ray fluorescence spectrometry: XRF;
high-resolution transmission electron microscopy: HRTEM;
elemental analysis;
energy-dispersive spectrometry analysis: EDS or EDX (“energy dispersive X-ray spectrometry”);
secondary ion mass spectrometry: SIMS.

Generally, and particularly for SIMS, the measurement device may be previously calibrated on a reference sample according to a conventional operating mode within the abilities of those skilled in the art.

### SPECIFIC EMBODIMENTS OF THE METHOD ACCORDING TO THE INVENTION

The ALD deposition of the MYₓ thin film is carried out in an enclosure where the precursors of metal M and of element Y are introduced separately. In accordance with the implementation of the ALD technique, the precursors are introduced into a deposition chamber, in alternated fashion, and in gaseous form, to control the forming of the thin film. Indeed, a simultaneous introduction of the precursors might generate a reaction between the latter before reaching the substrate having the thin film formed thereon.

The precursors are generally introduced in gaseous form. They are transported to the deposition area by an inert gas (argon or nitrogen, for example). However, and according to a specific embodiment, they may be introduced in diluted form in a sufficiently volatile solvent of low reactivity (toluene, benzene, hexane, for example). This diluted precursor solution is then atomized in the carrier gas flow in the form of a spray.

Each precursor is introduced by “pulse”. Each pulse corresponds to the transport to the substrate of one of the precursors by a gas flow, for a time period necessary to obtain an optimum coverage of the substrate. It will be within the abilities of those skilled in the art to adjust the necessary parameters according to conventional ALD methods. The duration of a pulse may particularly depend on the nature of the instrument used. Thus, and as a non-limiting example, it may be in the range from a few milliseconds to several minutes, for example, from 100 milliseconds to 10 minutes.

According to a specific embodiment, the ALD deposition comprises introducing into a deposition chamber at least one precursor of metal M, and then introducing at least one precursor of element Y.

According to another specific embodiment, the ALD deposition comprises introducing into a deposition chamber at least one precursor of element Y, and then introducing at least one precursor of metal M.

The ALD deposition may thus comprise the steps of:
a) introducing a first precursor of metal M or of element Y into a deposition chamber;
b) optionally, purging the deposition chamber with an inert gas (argon or nitrogen, for example) to eliminate the species which have not reacted;
c) introducing a second precursor into the deposition chamber, the second precursor being a precursor of metal M when the first precursor is a precursor of element Y or a precursor of element Y when the first precursor is a precursor of metal M;
d) optionally, purging the deposition chamber with an inert gas (argon or nitrogen, for example) to eliminate the species which have not reacted;
e) repeating steps a) to d).

Generally, the introduction of the first precursor is preceded by a step of purging the deposition chamber. The inert purge gas generally is argon or nitrogen. It may be any gas which does not react with the precursors.

Steps a) to d) are generally repeated until a thin film having the desired thickness is obtained. The precursors used in the so-called repetition steps may be identical to the precursors initially used or different therefrom. For example, precursors of molybdenum of different nature may be used to form a MoYₓ thin film. Precursors of different metals may also be used to form a hybrid MYₓ thin film, with M=Mo+W. The same applies for the precursor(s) of Y.

Thus, and generally, the ALD deposition may comprise, on the one hand, the introduction of precursors of the tungsten and/or molybdenum metals, and on the other hand the introduction of precursors of the sulphur and/or selenium elements. This specific embodiment enables to form a hybrid MYₓ thin film, where M=(Mo and/or W) and Y=(S and/or Se).

On introduction of the first precursor, the surface of the substrate is advantageously saturated with metal M or with element Y, to form a homogeneous deposition which advantageously covers the entire substrate. Each subsequent introduction of a precursor of M or of Y enables to saturate the surface of the previously-deposited film.

As already mentioned, the precursors of metal M and of element Y are introduced in alternated fashion. The order of introduction may in particular depend on the nature of the substrate.

For example, and according to a specific embodiment, particularly when the substrate is of metal oxide or organic oxide type, the method may comprise the following pulse sequence:
precursor of metal M,
precursor of element Y,
precursor of metal M,
precursor of element Y.

According to another specific embodiment, particularly when the substrate is made of a metal (nickel, copper, or gold, for example), the method may comprise the following pulse sequence:
precursor of element Y,
precursor of metal M,
precursor of element Y,
precursor of metal M,
precursor of element Y.

It will be within the abilities of those skilled in the art to adapt the frequency and the repetition of the pulses according to the desired substrate coverage rate.

The ALD deposition particularly comprises taking the precursors to the temperature necessary to obtain a vapor pressure sufficient for the working pressure. The precursor is then transported to the substrate by a gas flow which may be inert or reactive. It will be within the abilities of those skilled in the art to adjust the quantity of precursor to be injected for each pulse, and to implement the ALD deposition.

In the context of the present invention, the ALD deposition of the MYₓ thin film is performed at a temperature lower than or equal to 350° C. In other words, and as already indicated, the substrate temperature is lower than or equal to 350° C. It more advantageously ranges from 0 to 350° C., and more advantageously still from 120 to 300° C. According to another particularly advantageous embodiment, the temperature is in the range from 20 to 350° C., advantageously from 20 to 300° C.

The deposition temperature may be adapted according to the nature of the couple of precursors used. It will be within the abilities of those skilled in the art to adapt the deposition temperature according to the nature of the couple of precursors used.

However, the ALD deposition is advantageously performed at the same temperature for all the couples of precursors used.

It may also be performed under a low pressure.

Generally, the method according to the invention is applicable to a large-scale production, and enables to obtain a MYₓ thin film while providing the following technical effects:
accurate control of the thickness of the deposit;
the possibility of preparing hybrid thin films;
lack of impurities related to elements O, F, Cl, Br, and I;
deposition performed at low temperature (≦350° C.);
no release of dihalogen compounds or of hydrogen halogenides which would not only corrode the reactor, but also the deposit and the substrate.

### Precursors

Generally, the precursors of metal M and of element Y are advantageously thermally stable at the ALD temperature. On the other hand, they have a vapor pressure suited to the working pressure and a reactivity enabling them to be implemented by ALD, at a temperature lower than or equal to 350° C.

The precursors of metal M are compounds comprising ligands, that is, groups directly bonded to metal M. On forming of the MYₓ thin film, such ligands are advantageously integrally substituted with elements Y. The ligands which are not substituted with elements Y are generally eliminated at the subsequent optional anneal step described hereafter.

As already indicated, the precursor of metal M is a compound of tungsten or of molybdenum comprising M-Z and/or M-M bonds with Z=C, N, H, and any combination of these atoms. The bonds may be simple, double, or triple covalent bonds. Advantageously, it only comprises M-Z bonds. However, and according to a specific embodiment, the metal of the precursor of metal M exclusively comprises simple and/or double bonds with nitrogen.

Further, the precursor of metal M comprises no halogens. It is also preferably hydrogen-free.

It generally is a monometal or bimetal compound. Preferably, it is a monometal compound having a degree of oxidation equal to 4 or 6.

Advantageously, the precursor of metal M is selected from the group comprising compounds Mo(NMe₂)₄; M(=N—CMe₃)₂(NMe₂)₂; Mo(NEtMe)₄; Mo(NEt₂)₄; and M₂(NMe₂)₆; with M=molybdenum or tungsten, Me=—CH₃, Et=—CH₂—CH₃.

More advantageously still, the precursor of metal M is Mo(NMe₂)₄, Mo(NEtMe)₄; Mo(=N—CMe₃)₂(NMe₂)₂; or W(=N—CMe₃)₂(NMe₂)₂. In this case, the temperature for implementing the method is advantageously in the range from 20 to 350° C.

As concerns the precursor of element Y, it is advantageously deprived of halogens and of oxygen.

Typically, the precursor of element Y may be selected from the group comprising YR); Y₂R; Y₂R₂; Y₃R₂; Y₂R₃ (with R=H and/or alkyl and/or allyl and/or aryl; and R=C in the case of Y₂R).

The above-mentioned alkyl group R is advantageously a linear or branched alkyl comprising from 1 to 8 carbon atoms, and more advantageously still from 1 to 4 carbon atoms.

The precursor of element Y may be used alone or mixed with hydrogen. The Y₂R₂ and Y₃R₂ compounds are advantageously used mixed with hydrogen. The hydrogen may advantageously be in plasma form.

The precursor of element Y may particularly be selected from the group comprising methyl disulphide; ethyl disulphide; methyl diselenide; ethyl diselenide; and 1,2-ethanedithiol (Y₂R₃=HS—C₂H₄—SH).

According to a preferred embodiment, the precursor of element Y may be: H₂Y alone; or
1,2-ethanedithiol (HS—CH₂CH₂—SH) alone; or
the H₂/Y₂R₂ mixture.

According to a specific embodiment, the way in which the precursor of element Y (alone or mixed with hydrogen) is employed (introduction into the deposition enclosure by ALD) may be plasma-assisted. The presence of a plasma may thus enable to lower the deposition temperature. Generally, this specific embodiment does not concern the precursor of metal M.

According to a preferred embodiment, the precursor of element Y is H₂Y, alone or mixed with hydrogen.

The introduction of the precursor of element Y into the deposition chamber may also be followed by a hydrogen pulse which enables to clean possible traces of remaining ligand and to reactivate the surface for the next pulse of the precursor of M.

As indicated hereabove, a mixture of precursors may also be used. For example, a possible mixture of hydrogen/alkyl polysulphide such as dimethyl disulphide DMDS or diethyl disulphide DEDS, may be used. This mixture generates in-situ a mixture of thiols and of H₂S when the temperature is greater than or equal to 150° C. and in the presence of Mo or W.

Further, the use of a mixture containing a precursor of element Y and hydrogen may have the following advantages:
possibility of obtaining an oxidizing or reducing mixture (capable of comprising a plurality of compounds which are precursors of element Y) according to temperature and to the hydrogen content, thus enabling to better control the Y/M ratio;
the presence of hydrogen promotes the forming of —YH groups at the substrate surface. The presence of such groups is particularly advantageous due to their better reactivity towards the precursor of metal M than —Y-alkyl groups;
as a variation, a hydrogen plasma may be used as a carrier gas for an alkyl disulphide or diselenide, thus enabling to lower the reaction temperature by forming radicals Y. of higher reactivity.

### Anneal

The method according to the invention may comprise an optional anneal step at the end of the forming of the thin film of formula MYₓ. It enables to form a crystalline thin film advantageously having formula MY₂. Indeed, on anneal, the possible excess of compound Y is eliminated. Accordingly, at the end of the anneal, x is advantageously equal to 2.

As already indicated, the ALD deposition enables to control the forming of the thin film which may be amorphous, partially crystalline, or totally crystalline at the end of the deposition.

However, and advantageously, the ALD temperature does not enable the MYₓ thin film to crystallize. This condition particularly enables to avoid the forming of crystals totally randomly oriented with respect to the substrate.

Thus, the nature of the precursors used enables to operate at a temperature lower than the crystallization temperature of material MYₓ. Only at the end of its forming can the MYₓ thin film be crystallized, during an anneal step.

The anneal step is thus particularly adapted to the cases where the deposited MYₓ film is amorphous or partially crystalline.

On anneal, the thin film is densified. Thus, and advantageously, the thin film forms a crystal lattice having its basal planes (slabs) advantageously stacked in planes parallel to the surface of the substrate on which it is formed.

Typically, the anneal temperature is advantageously in the range from 200 to 1,000° C., more advantageously from 350 to 700° C.

Advantageously, the anneal temperature may be in the range from 800 to 850° C. under argon, or from 450 to 500° C. under hydrogen.

Generally, the anneal is carried out under vacuum or under an inert atmosphere (nitrogen, argon . . . ) to avoid a reaction of the oxygen of air with the deposit. As a variation, it may be carried out under hydrogen to ease the crystallization, and eliminate the excess Y if necessary.

The advantages linked to the anneal step may be the following:
low roughness of the surface, as compared with prior art thin layers for which the high-temperature deposition generally promotes a growth at the crystallite border, which results in petal, microsphere, or microtube structures.
access to different crystal phases of MoS₂ according to temperature and to the duration of the anneal.
control of the orientation of the crystal planes according to the anneal conditions and to the nature of the substrate, with for example the possibility of obtaining crystal slabs having their basal planes oriented parallel to the plane of the substrate having the thin film deposited thereon.

### Substrate

As already indicated, the order of introduction of the M or Y precursors may depend on the nature of the substrate.

The deposition is performed on a substrate which may be heated, so that its temperature is sufficient to observe a self-limited growth with no residue or non-controlled thermal decomposition of the precursors.

The surface of the substrate having the thin film deposited thereon is advantageously made of a material selected from the group comprising a metal; a semiconductor; a polymer; an organic substrate; an inorganic oxide; a metal oxide; a metal sulphide; a metal selenide; an inorganic sulphide; and an inorganic selenide.

The semiconductor substrates may particularly be made of silicon or of germanium.

Generally, the surfaces having —OH, —SH, —SeH terminations are particularly adapted to the pulses of a metal precursor, that is, the initial introduction of a precursor of metal M while metal surfaces are generally better adapted to the initial introduction of the precursor of element Y.

According to a specific embodiment, before implementation of the method according to the invention, the substrate may be submitted to a chemical processing aiming at forming or at introducing the previously-mentioned —OH, —SH, or —SeH terminations. The controlled hydration of a support of metal oxide type will for example enable to make the surface reactive by forming —OH groups. Further, the grafting of compounds of chloro- or alkoxy-silane type having a functionality reactive towards the precursor of metal M may be implemented before the deposition of the MYₓ thin film.

### Thin Film and Use Thereof

The present invention relates to the MYx thin film capable of being obtained by the above-described method, but also to its use, particularly in electronics.

The fields of use of the thin film particularly include photovoltaics and the hydrogen evolution reaction (HER).

The MYₓ thin film may comprise a surface layer which is partially or totally oxidized, particularly by being exposed to air. In this case, it may be considered as a layer of protection of the MYₓ thin film material.

On the other hand, a surface layer (of graphite or metal oxide or metal nitride type) may be deliberately arranged at the end of the process to passivate the MYₓ film. This optional step may be carried out before or after the anneal.

The invention and the resulting advantages will better appear from the following non-limiting drawings and examples, provided as an illustration of the invention.

### DESCRIPTION OF THE DRAWINGS

FIG. 1 illustrates the general XPS spectrum of a MoS_{1.8} sample obtained according to the method of the invention.

FIG. 2 illustrates the high-resolution XPS spectrum (Mo_{3d} lines) of a MoS_{1.8} sample obtained according to the method of the invention.

FIG. 3 illustrates the high-resolution XPS spectrum (S₂ₚ lines) of a MoS_{1.8} sample obtained according to the method of the invention.

### EMBODIMENTS OF THE INVENTION

Deposition of a MoS_{1.8} thin film (M=Mo; Y=S; x=1.8) from tetrakis(dimethylamino)molybdenum (IV) and 1,2 ethanedithiol according to the method of the invention.

The deposition is performed on a SiO₂ substrate having a 275-nm thickness in an ALD reactor, by alternating pulses of tetrakis(dimethylamino)molybdenum (IV) Mo(NMe₂)₄ and 1,2-ethanedithiol, preceded by a purging cycle (60 sccm of argon at a 10-torr pressure, that is, 1,333 Pa, for 2 minutes). (1 sccm=1 standard cm³/minute).

The substrate (and the sample being formed) is maintained at 100° C. all along the deposition.

The tetrakis(dimethylamino)molybdenum (IV) is saturated at 20° C./10 Torr in a 40-sccm argon flow.

The duration of the pulse for the metal precursor is 5 minutes.

The 1,2-ethanedithiol (≧98%, from Sigma-Aldrich) is saturated at 20° C./760 Torr in a 60 cm³/minute argon flow.

The duration of the pulse for the sulphided precursor is 5 minutes.

In the end, five “metal precursor—purging—sulfur precursor—purging” cycles are carried out.

The sample is then annealed for 10 min at 800° C. under a continuous argon flow (10 Torr, 100 sccm).

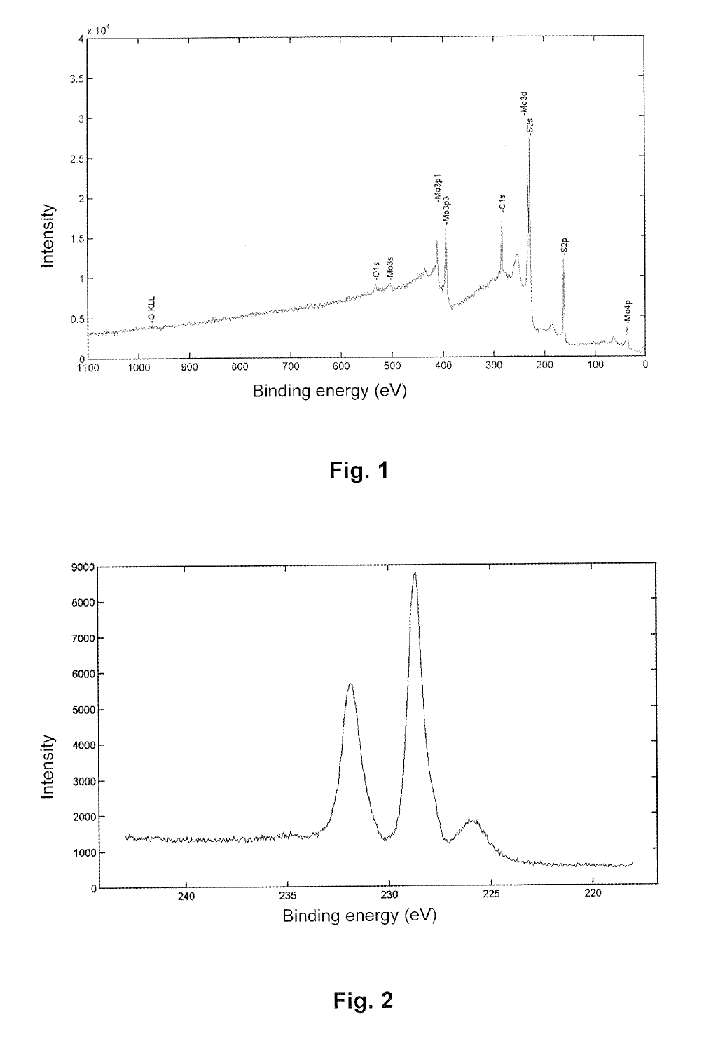

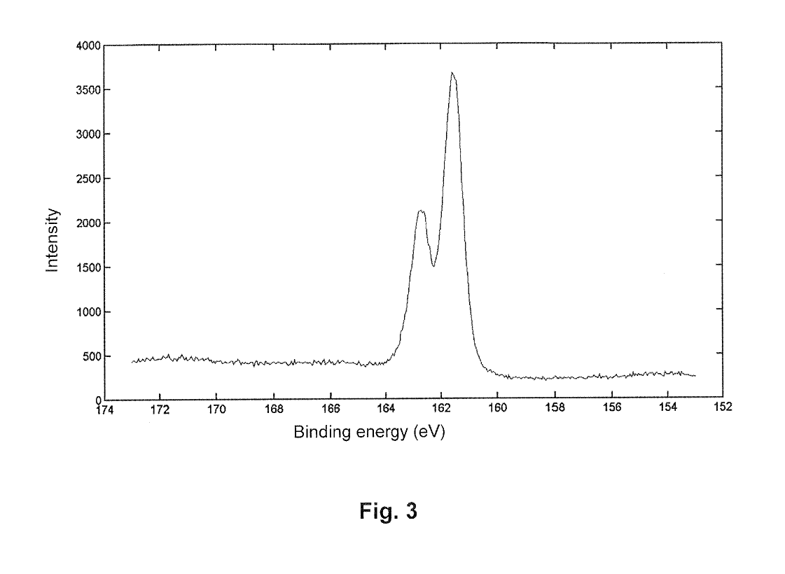

Analyses by XPS (X-ray photoelectron spectrometry) reveal a phase very close to the MoS₂ stoichiometry with a ratio S/Mo=1.8 (assessed from the Mo_{3d} and S₂ₚ lines, FIGS. 1 to 3).

1. A method of preparing by ALD a thin film of formula MYₓ, x being in the range from 1.5 to 3.1, according to which a deposition of MYₓ by ALD is performed on a substrate, from at least one precursor of metal M and at least one precursor of element Y;
M being tungsten and/or molybdenum;
the degree of oxidation of metal M in the precursor of metal M being in the range from 3 to 6;
the metal of the precursor of metal M only comprising simple or multiple bonds M-Z and/or M-M with Z=C, N, H, and any combination of these atoms;
Y being sulfur and/or selenium;
the substrate temperature being lower than or equal to 350° C.

2. The method of claim 1, wherein the ALD deposition comprises introducing into a deposition chamber at least one precursor of metal M, and then introducing at least one precursor of element Y.

3. The method of claim 1, wherein the ALD deposition comprises introducing into a deposition chamber at least one precursor of element Y, and then introducing at least one precursor of metal M.

4. The method of claim 1, wherein the ALD deposition comprises, on the one hand, introducing precursors of metals tungsten and/or molybdenum and, on the other hand, introducing precursors of elements sulphur and/or selenium.

5. The method of claim 1, wherein it comprises the steps of:
a) introducing a first precursor of metal M or of element Y into a deposition chamber;
b) purging the deposition chamber with an inert gas;
c) introducing a second precursor into the deposition chamber, the second precursor being a precursor of metal M when the first precursor is a precursor of element Y or a precursor of element Y when the first precursor is a precursor of metal M;
d) purging the deposition chamber with an inert gas;
e) repeating steps a) to d).

6. The method of claim 1, wherein the substrate temperature is in the range from 0 to 350° C., and advantageously from 120 to 300° C.

7. The method of any of claim 1, wherein the precursor of metal M is selected from the group comprising Mo(NMe₂)₄; M(=N—CMe₃)₂(NMe₂)₂; Mo(NEtMe)₄; Mo(NEt₂)₄, and M₂(NMe₂)₆; with M=molybdenum or tungsten, Me=—CH₃, Et=—CH₂—CH₃.

8. The method of claim 1, wherein the precursor of element Y is selected from the group comprising YR₂; Y₂R; Y₂R₂; Y₃R₂; and Y₂R₃, with R=H and/or alkyl and/or allyl and/or aryl, and R=C for Y₂R.

9. The method of claim 1, wherein the precursors of metal M and of element Y are deprived of halogens and oxygen.

10. The method of claim 1, wherein it comprises an anneal step after the forming of the thin film of formula MYₓ, the anneal temperature being in the range from 200 to 1,000° C.

11. The method of claim 1, wherein the substrate temperature is in the range from 20 to 350° C., advantageously from 20 to 300° C.

12. The method of claim 1, wherein the precursor of metal M is Mo(NMe₂)₄; Mo(NEtMe)₄; Mo(═N—CMe₃)₂(NMe₂)₂; or W(═N—CMe₃)₂(NMe₂)₂.

13. The method of claim 1, wherein the precursor of element Y is selected from the group comprising H₂Y; 1,2-ethanedithiol; and the H₂/Y₂R₂ mixture, with R=H and/or alkyl and/or allyl and/or aryl.

14. The method of claim 1, wherein the use of the precursor of element Y is plasma-assisted.

15. The method of claim 1, wherein the surface of the substrate having the thin film deposited thereon is made of a material selected from the group comprising a metal; a semiconductor; a polymer; an organic substrate; an inorganic oxide; a metal oxide; a metal sulphide; a metal selenide; an inorganic sulphide; and an inorganic selenide.
